(19) United States
(12) Patent Application Publication
(10) Pub. No.: US 2026/0349032 A1
(43) Pub. Date: Nov. 5, 2026

(54) BUILT-IN SELF-REPAIR FOR ARBITRARY DEFECTIVE INTERCONNECTS IN A MULTI-DIE IC DESIGN

(71) Applicant: NATIONAL TSING HUA UNIVERSITY, Hsinchu (TW)

(72) Inventors: Shi-Yu HUANG, Hsinchu (TW); Chi LAI, Hsinchu (TW)

(73) Assignee: NATIONAL TSING HUA UNIVERSITY, Hsinchu (TW)

(21) Appl. No.: 19/271,535

(22) Filed: Jul. 16, 2025

(30) Foreign Application Priority Data
May 2, 2025 (TW) 114116604

(51) Int. Cl. G01R 31/3185; G01R 31/317; H10W 20/20

(52) U.S. Cl. CPC G01R 31/31855; G01R 31/31726; G01R 31/318513; G01R 31/318536; G01R 31/318541; H10W 20/20

(57) ABSTRACT

An electronic device includes multiple interconnects including multiple spare interconnects and multiple dies electrically connected to each other through the interconnects. The die includes a master die and multiple slave dies. Each slave die includes a receiver wrapper circuit. The receiver wrapper circuit receives a pulse signal from the interconnects to obtain a test result. The master die includes a master controller and a driver wrapper circuit. The master controller sends out a mode configuration command. The driver wrapper circuit transmits the pulse signal to the interconnects, and selects one of the spare interconnects according to the test result. The master controller broadcasts the test result to the driver wrapper circuit and the receiver wrapper circuit. The receiver wrapper circuit selects said spare interconnect according to the test result.

### CROSS REFERENCE TO RELATED APPLICATIONS

This Application claims priority of Taiwan Application No. 114116604, filed on, May 2, 2025, the entirety of which is incorporated by reference herein.

### BACKGROUND OF THE INVENTION

### Field of the Invention

The present invention relates to an electronic device, and, in particular, it relates an electronic device with built-in self-repair interconnects.

### Description of the Related Art

In a chiplet integrated circuit (IC), multiple functional chips are integrated through chip-to-chip interconnects made in a common underlying interposer or redistribution layer. Even if a functioning die is known as a good die, its die-to-die interconnects are susceptible to manufacturing defects during the last-minute integration process, posing a threat to overall manufacturing yield. As the number of chips and the number of interconnects between chips in chiplet ICs continue to increase, this problem has become more serious. How to achieve a self-repairing function of chip-to-chip interconnects in the chiplet IC has become an important issue.

### BRIEF SUMMARY OF THE INVENTION

An embodiment of the present invention provides an electronic device. The electronic device includes multiple interconnects including multiple spare interconnects and multiple dies electrically connected to each other through the interconnects. The die includes a master die and multiple slave dies. Each slave die includes a receiver wrapper circuit. The receiver wrapper circuit receives a pulse signal from the interconnects to obtain test result. The master die includes a master controller and a driver wrapper circuit. The master controller sends out a mode configuration command. The driver wrapper circuit transmits the pulse signal to the interconnects, and selects one of the spare interconnects according to the test result. The master controller broadcasts the test result to the driver wrapper circuit and the receiver wrapper circuit. The receiver wrapper circuit selects the aforementioned spare interconnect according to the test result.

According to the electronic device described above, the mode configuration command includes a reset command, a test command, a synchronization command, or a repair command.

According to the electronic device described above, the master die and each slave die includes a control channel register and a data channel register. The control channel register receives the mode configuration command from the master controller through a control channel. The data channel register receives the test result from the master controller through a data channel, and sends the test result to the driver wrapper circuit or the receiver wrapper circuit according to the synchronization command.

According to the electronic device described above, the slave dies include multiple middle slave dies (104,106) and an edge slave die (108). The middle slave dies are electrically connected between the master die and the edge slave die. Each middle slave die includes a slave driver wrapper circuit (118,120) and a multiplexer (142,144). The slave driver wrapper circuit transmits the pulse signal to the interconnects according to the mode configuration command, or receives the test result from the master controller, or selects the aforementioned spare interconnect according to the test result. The multiplexer includes an input end, a first output end, a second output end, and a control end. The input end is electrically connected to the data channel register. The first output end is electrically connected to the receiver wrapper circuit. The second output end is electrically connected to the slave driver wrapper circuit. The control end is electrically connected to the control channel register.

According to the electronic device described above, the multiplexer sends data stored in the data channel register to the receiver wrapper circuit or the slave driver wrapper circuit according to an address identification signal; the control channel register of each middle slave die sends the address identification signal to the multiplexer.

According to the electronic device described above, the slave dies include a first middle slave die and a second middle slave die. The interconnects include a first interconnect group, a second interconnect group, and a third interconnect group. The first interconnect group is electrically connected between the master die and the first middle slave die. The second interconnect group is electrically connected between the first middle slave die and the second middle slave die. The third interconnect group is electrically connected between the second middle slave die and the edge slave die. The present invention does not

According to the electronic device described above, the master controller sequentially sends the test command to the control channel register of the master die, the control channel register of the first middle slave die, and the control channel register of the second middle slave die through the control channel, so that the driver wrapper circuit transmits the pulse signal to the first interconnect group, then the slave driver wrapper circuit of the first middle slave die transmits the pulse signal to the second interconnect group, and finally the slave driver wrapper circuit of the second middle slave die transmits the pulse signal to the third interconnect group.

According to the electronic device described above, the receiver wrapper circuit of the first middle slave die receives the pulse signal from the first interconnect group to obtain first test result. The receiver wrapper circuit of the second middle slave die receives the pulse signal from the second interconnect group to obtain second test result. The receiver wrapper circuit of the edge slave die receives the pulse signal from the third interconnect group to obtain third test result.

According to the electronic device described above, the master controller receives the first test result, the second test result, and the third test result through a test result scan chain.

According to the electronic device described above, the master controller sequentially sends the first test result, the second test result, and the third test result to the data channel register of the master die, the data channel register of the first middle slave die, the data channel register of the second middle slave die, and the data channel register of the edge slave die through the data channel.

According to the electronic device described above, the master controller sends the synchronization command to the control channel register of the master die and the control channel register of the first middle slave die through the control channel, so that the data channel register of the master die sends the first test result to the driver wrapper circuit of the master die, and the data channel register of the first middle slave die sends the first test result to the receiver wrapper circuit of the first middle slave die.

According to the electronic device described above, the master controller sends the synchronization command to the control channel register of the first middle slave die and the control channel register of the second middle slave die through the control channel, so that the data channel register of the first middle slave die sends the second test result to the slave driver wrapper circuit of the first middle slave die, and the data channel register of the second middle slave die sends the second test result to the receiver wrapper circuit of the second middle slave die.

According to the electronic device described above, the master controller sends the synchronization command to the control channel register of the second middle slave die and the control channel register of the edge slave die through the control channel, so that the data channel register of the second middle slave die sends the third test result to the slave driver wrapper circuit of the second middle slave die, and the data channel register of the edge slave die sends the third test result to the receiver wrapper circuit of the edge slave die.

According to the electronic device described above, the master controller sends the repair command to the control channel register of the master die, so that the driver wrapper circuit of the master die selects a spare interconnect in the first interconnect group according to the first test result to eliminate a faulty interconnect in the first interconnect group.

According to the electronic device described above, the master controller sends the repair command to the control channel register of the first middle slave die, so that the receiver wrapper circuit of the first middle slave die selects a spare interconnect in the first interconnect group according to the first test result to eliminate a faulty interconnect in the first interconnect group, and the slave driver wrapper circuit of the first middle slave die selects a spare interconnect in the second interconnect group according to the second test result to eliminate a faulty interconnect in the second interconnect group.

According to the electronic device described above, the master controller sends the repair command to the control channel register of the second middle slave die, so that the receiver wrapper circuit of the second middle slave die selects a spare interconnect in the second interconnect group according to the second test result to eliminate a faulty interconnect in the second interconnect group, and the slave driver wrapper circuit of the second middle slave die selects a spare interconnect in the third interconnect group according to the third test result to eliminate a faulty interconnect in the third interconnect group.

According to the electronic device described above, the master controller sends the repair command to the control channel register of the edge slave die, so that the receiver wrapper circuit of the edge slave die selects a spare interconnect in the third interconnect group according to the third test result to eliminate a faulty interconnect in the third inter-connect group.

According to the electronic device described above, the driver wrapper circuit or the slave driver wrapper circuit includes a plurality of driver units. Each driver unit includes a transmitting unit, a selector, and a switch circuit. The transmitting unit receives a double-pulse signal and generate the pulse signal according to the double-pulse signals. The selector receives the test result of the pulse signal, and outputs a selection signal according to the test result. The switch circuit sends the pulse signal to said spare interconnect according to the selection signal from the selector.

According to the electronic device described above, the receiver wrapper circuit includes a plurality of receiver units. Each receiver unit includes a capturing unit, a selector, and a switch circuit. The capturing unit receives the pulse signal that has passed through the interconnects, and generates the test result according to the pulse signal that has passed through the interconnects. The selector receives the test result of the pulse signal, and outputs a selection signal according to the test result. The switch circuit receives the pulse signal through the aforementioned spare interconnect according to the selection signal from the selector.

### BRIEF DESCRIPTION OF THE DRAWINGS

The present invention can be more fully understood by reading the subsequent detailed description and examples with references made to the accompanying drawings.

FIG. 1 is a schematic diagram of an electronic device 100 in accordance with some embodiments of the present invention.

FIG. 2 is a flow chart of a method for self-repairing built-in interconnects in the electronic device 100 in FIG. 1 in accordance with some embodiments of the present invention.

FIG. 3 is a schematic diagram of the electronic device 100 in FIG. 1 performing a pulse-vanishing test in accordance with some embodiments of the present invention.

FIG. 4 is a schematic diagram of the electronic device 100 in FIG. 1 performing test result synchronization in accordance with some embodiments of the present invention.

FIG. 5 is a schematic diagram of the electronic device 100 in FIG. 1 performing repair in accordance with some embodiments of the present invention.

FIG. 6 is a schematic diagram of a driver unit 600 in a driver wrapper circuit 112 of the electronic device 100 in FIG. 1 in accordance with some embodiments of the present invention.

FIG. 7 is a schematic diagram of a receiver unit 700 in a receiver wrapper circuit 114 of the electronic device 100 in FIG. 1 in accordance with some embodiments of the present invention.

FIG. 8 is a schematic diagram of an electronic device 800 in accordance with some embodiments of the present invention.

FIG. 9 is a waveform timing diagram of a first round of the method for self-repairing built-in interconnects in FIG. 2 executed by the electronic device 800 in FIG. 8 in accordance with some embodiments of the present invention.

FIG. 10 is a waveform timing diagram of a second round of the method for self-repairing built-in interconnects in FIG. 2 executed by the electronic device 800 in FIG. 8 in accordance with some embodiments of the present invention.

FIG. 11 is a waveform timing diagram of a third round of the method for self-repairing built-in interconnects in FIG. 2 executed by the electronic device 800 in FIG. 8 in accordance with some embodiments of the present invention.

### DETAILED DESCRIPTION OF THE INVENTION

In order to make the above purposes, features, and advantages of some embodiments of the present invention more comprehensible, the following is a detailed description in conjunction with the accompanying drawing.

Certain terms are used throughout the description and following claims to refer to particular components. As one skilled in the art will understand, electronic equipment manufacturers may refer to a component by different names. This document does not intend to distinguish between components that differ in name but not function. It is understood that the words “comprise”, “have” and “include” are used in an open-ended fashion, and thus should be interpreted to mean “include, but not limited to . . . ”. Thus, when the terms “comprise”, “have” or “include” used in the present invention are used to indicate the existence of specific technical features, values, method steps, operations, units or components. However, it does not exclude the possibility that more technical features, numerical values, method steps, work processes, units, components, or any combination of the above can be added.

The directional terms used throughout the description and following claims, such as: “on”, “up”, “above”, “down”, “below”, “front”, “rear”, “back”, “left”, “right”, etc., are only directions referring to the drawings. Therefore, the directional terms are used for ex-plaining and not used for limiting the present invention. Regarding the drawings, the drawings show the general characteristics of methods, structures, or materials used in specific embodiments. However, the drawings should not be construed as defining or limiting the scope or properties encompassed by these embodiments. For example, for clarity, the relative size, thickness, and position of each layer, each area, or each structure may be reduced or enlarged.

When the corresponding component such as layer or area is referred to as being “on another component”, it may be directly on this other component, or other components may exist between them. On the other hand, when the component is referred to as being “directly on another component (or the variant thereof)”, there is no component between them. Furthermore, when the corresponding component is referred to as being “on another component”, the corresponding component and the other component have a disposition relationship along a top-view/vertical direction, the corresponding component may be below or above the other component, and the disposition relationship along the top-view/vertical direction is determined by the orientation of the device.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, and “third” are used to describe components. They are not used to indicate the priority order of or advance relationship, but only to distinguish components with the same name.

It should be noted that the technical features in different embodiments described in the following can be replaced, recombined, or mixed with one another to constitute another embodiment without depart in from the spirit of the present invention.

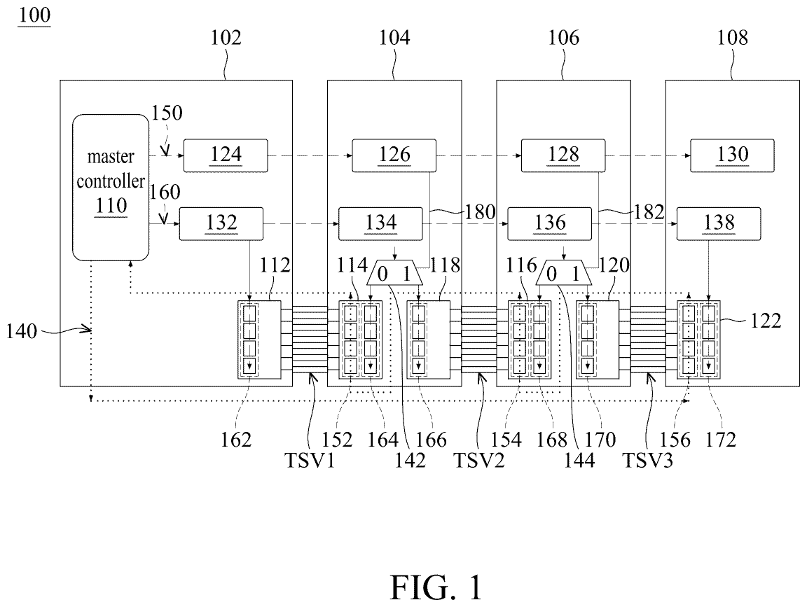

FIG. 1 is a schematic diagram of an electronic device 100 in accordance with some embodiments of the present invention. As shown in FIG. 1, the electronic device 100 includes a plurality of interconnects and a plurality of dies. In detail, the interconnects include interconnects TSV1, interconnects TSV2, and interconnects TSV3. The dies include a master die 102, a first middle slave die 104, a second middle slave die 106, and an edge slave die 108. The interconnects TSV1 are electrically connected between the master die 102 and the first middle slave die 104. The interconnects TSV2 are electrically connected between the first middle slave die 104 and the second middle slave die 106. The interconnects TSV3 are electrically connected between the second middle slave die 106 and the edge slave die 108. The interconnects TSV1, TSV2, and TSV3 all include a plurality of spare interconnects. In some embodiments, the interconnects TSV1, TSV2, and TSV3 all include two spare interconnects respectively, but the present invention is not limited thereto.

In some embodiments of FIG. 1, the master die 102 includes a master controller 110, a driver wrapper circuit 112, a control channel register 124, and a data channel register 132. The first middle slave die 104 includes a receiver wrapper circuit 114, a slave driver wrapper circuit 118, a control channel register 126, a data channel register 134, and a multiplexer 142. The second middle slave die 106 includes a receiver wrapper circuit 116, a slave driver wrapper circuit 120, a control channel register 128, a data channel register 136, and a multiplexer 144. The edge slave die 108 includes a receiver wrapper circuit 122, a control channel register 130, and a data channel register 138.

In the master die 102, the master controller 110 sends out a mode configuration command. In some embodiments, the mode configuration command includes a reset command, a test command, a synchronization command, or a repair command. The master controller sequentially broadcasts the test result to the driver wrapper circuit 112, the receiver wrapper circuit 114, the receiver wrapper circuit 116, and the receiver wrapper circuit 122. The driver wrapper circuit 112 transmits the pulse signal to the interconnects TSV1, and selects the aforementioned spare interconnect from among the interconnects TSV1 according to the test result. The control channel register 124 receives the mode configuration command from the master controller 110 through the control channel 150. The data channel register 132 receives the test result from the master controller 110 through the data channel 160, and sends the test result to the driver wrapper circuit 112 according to the synchronization command. The driver wrapper circuit 112 includes a register 162 to store the test result from the master controller 110.

In the first middle slave die 104, the receiver wrapper circuit 114 receives the pulse signal from the interconnects TSV1 to obtain the test result. The receiver wrapper circuit 114 includes a register 152 and a register 164. The register 152 is used to store the test result of the pulse signal from the interconnects TSV1. The register 164 is used to store the test result from the master controller 110. According to the mode configuration command, the slave driver wrapper circuit 118 transmits the pulse signal to the interconnects TSV2, or it receives the test result from the master controller 110> alternatively, it may select one of the spare interconnects from among all of the interconnects TSV2 according to the test result. The slave driver wrapper circuit 118 includes a register 166 to store the test result from the master controller 110.

In the first middle slave die 104, the control channel register 126 receives the mode configuration command from the master controller 110 through the control channel 150. The data channel register 134 receives the test result from the master controller 110 through the data channel 160, and sends the test result to the receiver wrapper circuit 114 or the slave driver wrapper circuit 118 according to the synchronization command. The multiplexer 142 includes an input end, a first output end, a second output end, and a control end. The input end of the multiplexer 142 is electrically connected to the data channel register 134. The first output end of the multiplexer 142 is electrically connected to the receiver wrapper circuit 114. The second output end of the multiplexer 142 is electrically connected to the slave driver wrapper circuit 118. The control end of the multiplexer 142 is electrically connected to the control channel register 126. The multiplexer 142 sends the data stored in the data channel register 134 to the receiver wrapper circuit 114 or the slave driver wrapper circuit 118 according to an address identification signal 180. The control channel register 126 sends the address identification signal 180 to the multiplexer 142.

In the second middle slave die 106, the receiver wrapper circuit 116 receives the pulse signal from the interconnects TSV2 to obtain the test result. The receiver wrapper circuit 116 includes a register 154 and a register 168. The register 154 is used to store the test result of the pulse signal from the interconnects TSV2. The register 168 is used to store the test result from the master controller 110. According to the mode configuration command, the slave driver wrapper circuit 120 transmits the pulse signal to the interconnects TSV3, or receives the test result from the master controller 110, or selects one of the spare interconnects TSV3 according to the test result. The slave driver wrapper circuit 120 includes a register 170 to store the test result from the master controller 110.

In the second middle slave die 106, the control channel register 128 receives the mode configuration command from the master controller 110 through the control channel 150. The data channel register 136 receives the test result from the master controller 110 through the data channel 160, and sends the test result to the receiver wrapper circuit 116 or the slave driver wrapper circuit 120 according to the synchronization command. The multiplexer 144 includes an input end, a first output end, a second output end, and a control end. The input end of the multiplexer 144 is electrically connected to the data channel register 136. The first output end of the multiplexer 144 is electrically connected to the receiver wrapper circuit 116. The second output end of the multiplexer 144 is electrically connected to the slave driver wrapper circuit 120. The control end of the multiplexer 144 is electrically connected to the control channel register 128. The multiplexer 144 sends the data stored in the data channel register 136 to the receiver wrapper circuit 116 or the slave driver wrapper circuit 120 according to an address identification signal 182. The control channel register 128 sends the address identification signal 182 to the multiplexer 144.

In the edge slave die 108, the receiver wrapper circuit 122 receives the pulse signal from the interconnects TSV3 to obtain the test result. The receiver wrapper circuit 122 includes a register 156 and a register 172. The register 156 is used to store the test result of the pulse signal from the interconnects TSV3. The register 172 is used to store the test result from the master controller 110. The control channel register 130 receives the mode configuration command from the master controller 110 through the control channel 150. The data channel register 138 receives the test result from the master controller 110 through the data channel 160, and transmits the test result to the receiver wrapper circuit 122 according to the synchronization command.

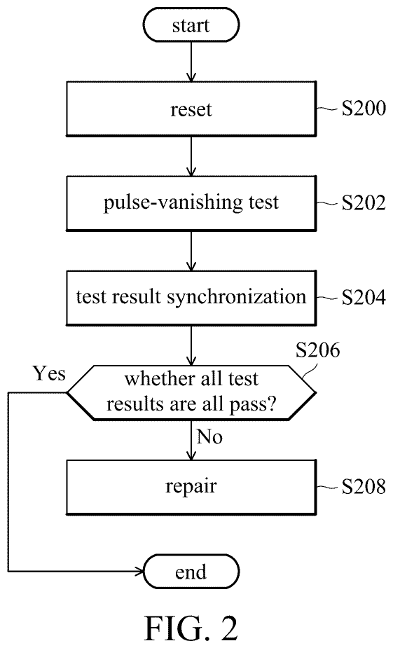

FIG. 2 is a flow chart of a method for self-repairing built-in interconnects in the electronic device 100 in FIG. 1 in accordance with some embodiments of the present invention. As shown in FIG. 2, the method for self-repairing built-in interconnects includes reset (step S200), pulse-vanishing test (step S202), test result synchronization (step S204), whether all test results are all pass (step S206), and repair (step S208). In some embodiments of FIG. 2, step S200 is used to reset the data stored in all registers in the electronic device 100. In step S200, the master controller 110 sends the reset command to the control channel registers 124, 126, 128, and 130 through the control channel 150, so that the data channel registers 132~138, registers 154~156, and registers 162-172 are reset.

In step S202, the master controller 110 sequentially sends the test command to the control channel register 124 of the master die 102, the control channel register 126 of the first middle slave die 104, and the control channel register 128 of the second middle slave die 106 through the control channel 150, so that the driver wrapper circuit 112 transmits the pulse signal to the interconnects TSV1. Then, the slave driver wrapper circuit 118 of the first middle slave die 104 transmits the pulse signal to the interconnects TSV2. Finally, the slave driver wrapper circuit 120 of the second middle slave die 106 transmits the pulse signal to the interconnects TSV3.

In step S202, the receiver wrapper circuit 114 of the first middle slave die 104 receives the pulse signal from the interconnects TSV1 to obtain first test result. The receiver wrapper circuit 116 of the second middle slave die 106 receives the pulse signal from the interconnects TSV2 to obtain second test result. The receiver wrapper circuit 116 of the edge slave die 108 receives the pulse signal from the interconnects TSV3 to obtain third test result. After that, the master controller 110 receives the first test result, the second test result, and the third test result through a test result scan chain (TDI-TDO) 140.

In step S204, the master controller 110 sequentially sends the first test result, the second test result, and the third test result to the data channel register 132 of the master die 102, the data channel register 134 of the first middle slave die 104, the data channel register 136 of the second middle slave die 106, and the data channel register 138 of the edge slave die 108 through the data channel 160.

In step S204, the master controller 110 sends the synchronization command to the control channel register 124 of the master die 102 and the control channel register 126 of the first middle slave die 104 through the control channel 150, so that the data channel register 132 of the master die 102 sends the first test result to the driver wrapper circuit 112 of the master die 102, and the data channel register 134 of the first middle slave die 104 sends the first test result to the receiver wrapper circuit 114 of the first middle slave die 104.

Next, in step S204, the master controller 110 sends the synchronization command to the control channel register 126 of the first middle slave die 104 and the control channel register 128 of the second middle slave die 106 through the control channel 150, so that the data channel register 134 of the first middle slave die 104 sends the second test result to the slave driver wrapper circuit 118 of the first middle slave die 104, and the data channel register 136 of the second middle slave die 106 sends the second test result to the receiver wrapper circuit 116 of the second middle slave die 106.

Then, the master controller 110 sends the synchronization command to the control channel register 128 of the second middle slave die 106 and the control channel register 130 of the edge slave die 108 through the control channel 150, so that the data channel register 136 of the second middle slave die 106 sends the third test result to the slave driver wrapper circuit 120 of the second middle slave die 106, and the data channel register 138 of the edge slave die 108 sends the third test result to the receiver wrapper circuit 122 of the edge slave die 108.

If the first test result, the second test result, and the third test result are all passed in step S206, then the process ends. If the first test result, the second test result, and the third test result are not all passed in step S206, then step S208 is executed.

In step S208, the master controller 110 sends the repair command to the control channel register 124 of the master die 102 through the control channel 150, so that the driver wrapper circuit 112 of the master die 102 selects a spare interconnect in the interconnects TSV1 according to the first test result to eliminate a faulty interconnect in the interconnects TSV1. The master controller 110 sends the repair command to the control channel register 126 of the first middle slave die 104 through the control channel 150, so that the receiver wrapper circuit 114 of the first middle slave die 104 selects a spare interconnect in the interconnects TSV1 according to the first test result to eliminate a faulty interconnect in the interconnects TSV1, and the slave driver wrapper circuit 118 of the first middle slave die 104 selects a spare interconnect in the interconnects TSV2 according to the second test result to eliminate a faulty interconnect in the interconnects TSV2.

In step S208, the master controller 110 sends the repair command to the control channel register 128 of the second middle slave die 106 through the control channel 150, so that the receiver wrapper circuit 116 of the second middle slave die 106 selects a spare interconnect in the interconnects TSV2 according to the second test result to eliminate a faulty interconnect in the interconnects TSV2, and the slave driver wrapper circuit 120 of the second middle slave die 106 selects a spare interconnect in the interconnects TSV3 according to the third test result to eliminate a faulty interconnect in the interconnects TSV3.

In step S208, the master controller 110 sends the repair command to the control channel register 130 of the edge slave die 108, so that the receiver wrapper circuit 122 of the edge slave die 108 selects a spare interconnect in the interconnects TSV3 according to the third test result to eliminate a faulty interconnect in the interconnects TSV3.

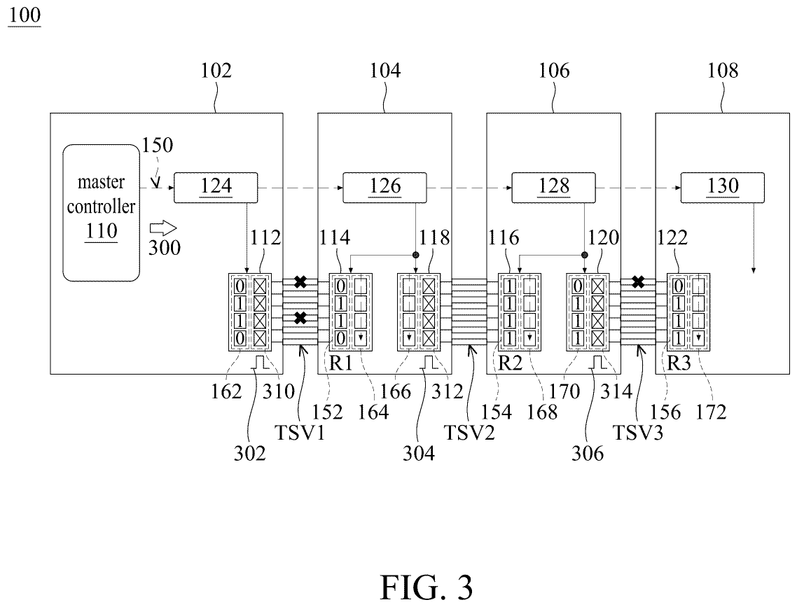

FIG. 3 is a schematic diagram of the electronic device 100 in FIG. 1 performing a pulse-vanishing test in accordance with some embodiments of the present invention. As shown in FIG. 3, the master controller 110 sequentially sends a mode configuration command 300 to the control channel register 124 of the master die 102, the control channel register 126 of the first middle slave die 104, and the control channel register 128 of the second middle slave die 106 through the control channel 150. In some embodiments of FIG. 3, the mode configuration command 300 is the test command. In detail, first, the master controller sends the test command to the control channel register 124 of the maser die 102 through the control channel 150, so that the driver wrapper circuit 112 transmits a pulse signal 302 to the interconnects TSV1. The register 152 of the receiver wrapper circuit 114 in the first middle slave die 104 obtains first test result R1. The first test result R1 may be “0110”, for example. That is, the 1st and 4th interconnects arranged from top to bottom in interconnect TSV1 are faulty. In some embodiments of FIG. 3, the driver wrapper circuit 112 includes a plurality of driver units 310 to sequentially transmit the pulse signal to the interconnects TSV1.

Then, the master controller 110 sends the test command to the control channel register 126 of the first middle slave die 104 through the control channel 150, so that the slave driver wrapper circuit 118 transmits a pulse signal 304 to the interconnects TSV2. The register 154 of the receiver wrapper circuit 116 in the second middle slave die 106 obtains second test result R2. The second test result R2 may be “1111”, for example. That is, the interconnects TSV2 all pass the test. In some embodiments of FIG. 3, the slave driver wrapper circuit 118 includes a plurality of driver units 312 to sequentially transmit the pulse signal to the interconnects TSV2.

Afterwards, the master controller 110 sends the test command to the control channel register 128 of the second middle slave die 106 through the control channel 150, so that the slave driver wrapper circuit 120 transmits a pulse signal 306 to the interconnects TSV3. The register 156 of the receiver wrapper circuit 122 in the edge slave die 106 obtains third test result R3. The third test result R3 may be “0111”, for example. That is, the 1^{st} interconnect arranged from top to bottom in the interconnects TSV3 is faulty. In some embodiments of FIG. 3, the slave driver wrapper circuit 120 includes a plurality of driver units 314 to sequentially transmit the pulse signal to the interconnects TSV3.

In some embodiments of FIG. 3, the master controller 110 receives the first test result R1, the second test result R2, and the third test result R3 through the test result scan chain (TDI-TDO) 140. For example, the master controller 110 receives data “011011110111” through the test result scan chain 140.

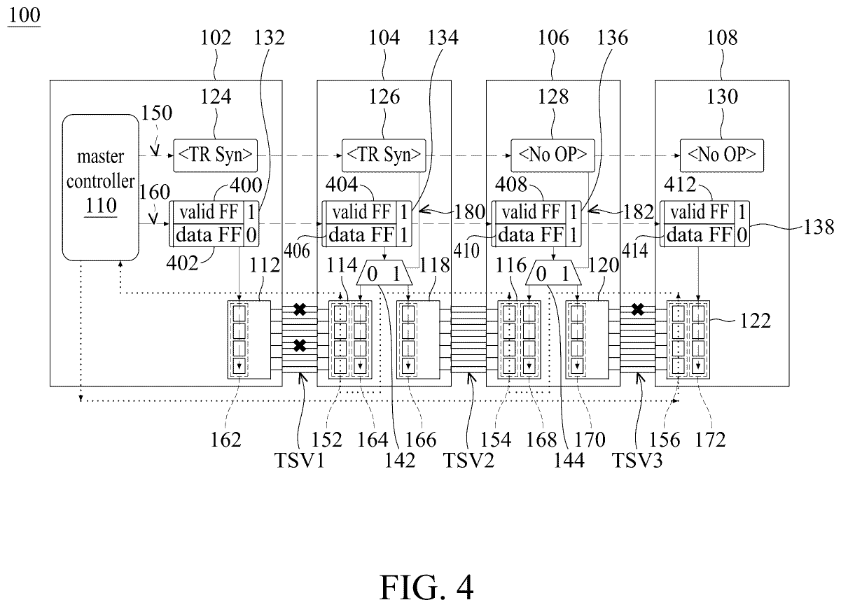

FIG. 4 is a schematic diagram of the electronic device 100 in FIG. 1 performing test result synchronization in accordance with some embodiments of the present invention. As shown in FIG. 4, the data channel register 132 includes a valid flip-flop (FF) 400 and a data flip-flop 402. The data channel register 134 includes a valid flip-flop 404 and a data flip-flop 406. The data channel register 136 includes a valid flip-flop 408 and a data flip-flop 410. The data channel register 138 includes a valid flip-flop 412 and a data flip-flop 414. The valid flip-flop 400 is used to indicate that the data in the data flip-flop 402 is valid. Similarly, the valid flip-flop 404 is used to indicate that the data in the data flip-flop 406 is valid. The valid flip-flop 408 is used to indicate that the data in the data flip-flop 410 is valid. The valid flip-flop 412 is used to indicate that the data in the data flip-flop 414 is valid.

As shown in FIG. 3, since the master controller 110 receives the data “011011110111” through the test result scan chain 140, the master controller 110 sequentially sends the first test result (for example, “0110”), the second test result (for example, “1111”), and the third test result (for example, “0111”) to the data channel register 132 of the master die 102, the data channel register 134 of the first middle slave die 104, the data channel register 136 of the second middle slave die 106, and the data channel register 138 of the edge slave die 108.

In some embodiments, FIG. 4 is used to show a data status after 4 clock cycles. For example, in the first clock cycle, the master controller 110 sends the first bit “0” in the first test result (for example, “0110”) to the data flip-flop 402 of the data channel register 132. When the master controller 110 sends the synchronization command to the control channel register 124 of the master die 102 and the control channel register 126 of the first middle slave die 104 through the control channel 150 (e.g., marked as <TR Syn>), the first bit “0” in the data flip-flop 402 is sent to the register 162 of the driver wrapper circuit 112. In the second clock cycle, the master controller 110 sends the second bit “1” in the first test result (for example, “0110”) to the data flip-flop 402 of the data channel register 132, and the data flip-flop 402 sends the first bit “0” in the first test result (for example, “0110”) to the data flip-flop 406 of the data channel register 134. When the master controller 110 sends the synchronization command to the control channel register 124 of the master die 102 and the control channel register 126 of the first middle slave die 104 (for example, marked as <TR Syn>) through the control channel 150, the second bit “1” in the data flip-flop 402 is sent to the register 162 of the driver wrapper circuit 112, and the first bit “0” in the data flip-flop 406 is sent to the register 164 of the receiver wrapper circuit 114.

In the third clock cycle, the master controller 110 sends the third bit “1” in the first test result (e.g., “0110”) to the data flip-flop 402 of the data channel register 132, the data flip-flop 402 sends the second bit “1” in the first test result (e.g., “0110”) to the data flip-flop 406 of the data channel register 134, and the data flip-flop 406 sends the first bit “0” in the first test result (e.g., “0110”) to the data flip-flop 410 of the data channel register 136. When the master controller 110 sends the synchronization command to the control channel register 124 of the master die 102 and the control channel register 126 of the first middle slave die 104 (e.g., marked as <TR Syn>) through the control channel 150, the third bit “1” in the data flip-flop 402 is sent to the register 162 of the driver wrapper circuit 112, and the second bit “1” in the data flip-flop 406 is sent to the register 164 of the receiver wrapper circuit 114.

In the fourth clock cycle, the master controller 110 sends the fourth bit “0” of the first test result (e.g., “0110”) to the data flip-flop 402 of the data channel register 132, the data flip-flop 402 sends the third bit “1” of the first test result (e.g., “0110”) to the data flip-flop 406 of the data channel register 134, the data flip-flop 406 sends the second bit “1” of the first test result (e.g., “0110”) to the data flip-flop 410 of the data channel register 136, and the data flip-flop 410 sends the first bit “1” of the first test result (e.g., “0110”) to the data flip-flop 414 of the data channel register 138. When the master controller 110 sends the synchronization command to the control channel register 124 of the master die 102 and the control channel register 126 of the first middle slave die 104 (for example, marked as <TR Syn>) through the control channel 150, the fourth bit “0” in the data flip-flop 402 is sent to the register 162 of the driver wrapper circuit 112, and the third bit “1” in the data flip-flop 406 is sent to the register 164 of the receiver wrapper circuit 114.

In some embodiments of FIG. 4, since the master controller 110 does not send the synchronization command to the control channel register 128 of the second middle slave die 106 and the control channel register 130 of the edge slave die 108 through the control channel 150, the control channel register 128 and the control channel register 130 are marked as <No OP> respectively.

In some embodiments of FIG. 4, in order to synchronize the first test result, the master controller 110 sends the synchronization command to the control channel register 124 of the master die 102 and the control channel register 126 of the first middle slave die 104 through the control channel 150, so that the data channel register 132 of the master die 102 sends the first test result to the driver wrapper circuit 112 of the master die 102, and the data channel register 134 of the first middle slave die 104 sends the first test result to the receiver wrapper circuit 114 of the first middle slave die 104.

In some embodiments of FIG. 4, in order to synchronize the second test result, the master controller 110 sends the synchronization command to the control channel register 126 of the first middle slave die 104 and the control channel register 128 of the second middle slave die 106 through the control channel 150, so that the data channel register 134 of the first middle slave die 104 sends the second test result to the slave driver wrapper circuit 118 of the first middle slave die 104, and the data channel register 136 of the second middle slave die 106 sends the second test result to the receiver wrapper circuit 116 of the second middle slave die 106.

In some embodiments of FIG. 4, in order to synchronize the third test result, the master controller 110 sends the synchronization command to the control channel register 128 of the second middle slave die 106 and the control channel register 130 of the edge slave die 108 through the control channel 150, so that the data channel register 136 of the second middle slave die 106 sends the third test result to the slave driver wrapper circuit 120 of the second middle slave die 106, and the data channel register 138 of the edge slave die 108 sends the third test result to the receiver wrapper circuit 122 of the edge slave die 108.

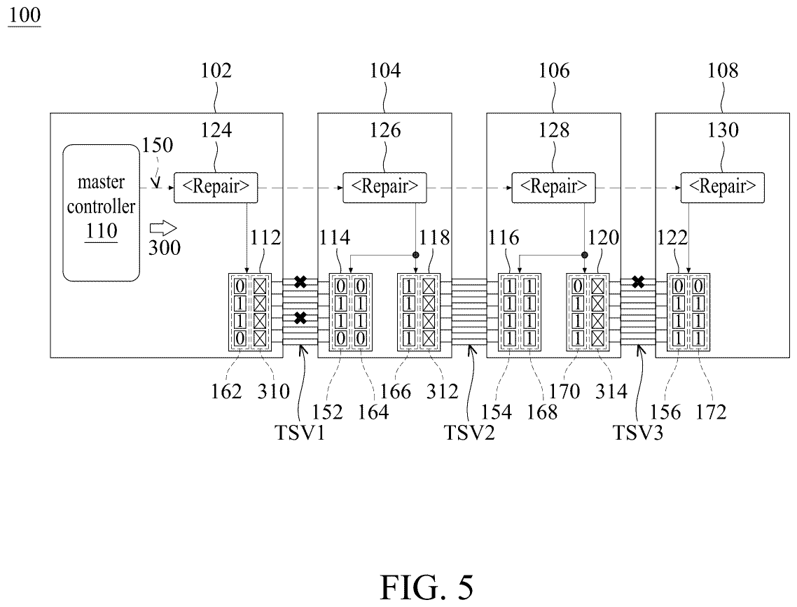

FIG. 5 is a schematic diagram of the electronic device 100 in FIG. 1 performing repair in accordance with some embodiments of the present invention. As shown in FIG. 5, the master controller 110 sends the repair command to the control channel register 124 (e.g., labeled as <Repair>) of the master die 102 through the control channel 150, so that the driver wrapper circuit 112 of the master die 102 selects a spare interconnect in the interconnects TSV1 (e.g., the 5th and 6th interconnects arranged from top to bottom in the interconnects TSV1) according to the first test result to eliminate a faulty interconnect in the interconnects TSV1 (e.g., the 1st and 4th interconnects arranged from top to bottom in the interconnects TSV1).

The master controller 110 sends the repair command to the control channel register 126 (e.g., marked as <Repair>) of the first middle slave die 104 through the control channel 150, so that the receiver wrapper circuit 114 of the first middle slave die 104 selects a spare interconnect in the interconnects TSV1 (e.g., the 5th and 6th interconnects arranged from top to bottom in the interconnects TSV1) according to the first test result to eliminate the faulty interconnects of the interconnects TSV1 (e.g., the 1st and 4th interconnects arranged from top to bottom in the interconnects TSV1), and the slave driver wrapper circuit 118 of the first middle slave die 104 selects a spare interconnect in the interconnects TSV2 according to the second test result to eliminate the faulty interconnects in the interconnects TSV2. In some embodiments of FIG. 5, according to the second test result, there is no fault in the interconnects TSV2, so the slave driver wrapper circuit 118 still sends the pulse signal to the 1st to 4^{th} interconnects arranged from top to bottom in the interconnects TSV2.

The master controller 110 sends the repair command to the control channel register 128 (e.g., marked as <Repair>) of the second middle slave die 106 through the control channel 150, so that the receiver wrapper circuit 116 of the second middle slave die 106 selects a spare interconnect in the interconnects TSV2 according to the second test result to eliminate the faulty interconnects in the interconnects TSV2, and the slave driver wrapper circuit 120 of the second middle slave die 106 selects a spare interconnect in the interconnects TSV3 (e.g., the 5^{th} interconnect arranged from top to bottom in the interconnects TSV3) according to the third test result to eliminate the faulty interconnects in the interconnects TSV3 (e.g., the 1^{st} interconnect arranged from top to bottom in the interconnects TSV3). In some embodiments of FIG. 5, according to the second test result, there is no fault in the interconnects TSV2, so the receiver wrapper circuit 116 still receives the pulse signal from the 1^{st} to 4^{th} interconnects arranged from top to bottom in the interconnects TSV2.

In some embodiments of FIG. 5, the master controller 110 sends the repair command to the control channel register 130 (e.g., marked as <Repair>) of the edge slave die 108 through the control channel 150, so that the receiver wrapper circuit 122 of the edge slave die 108 selects a spare interconnect in the interconnects TSV3 (e.g., the 5^{th} interconnect arranged from top to bottom in the interconnects TSV3) according to the third test result to eliminate the faulty interconnect in the interconnects TSV3 (e.g., the 1^{st} interconnect arranged from top to bottom in the interconnects TSV3). In some embodiments of FIG. 5, the master controller 110 sends the repair command to the control channel register 124 of the master die 102, the control channel register 126 of the first middle slave die 104, the control channel register 128 of the second middle slave die 106, and the control channel register 130 of the edge slave die 108 simultaneously through the control channel 150.

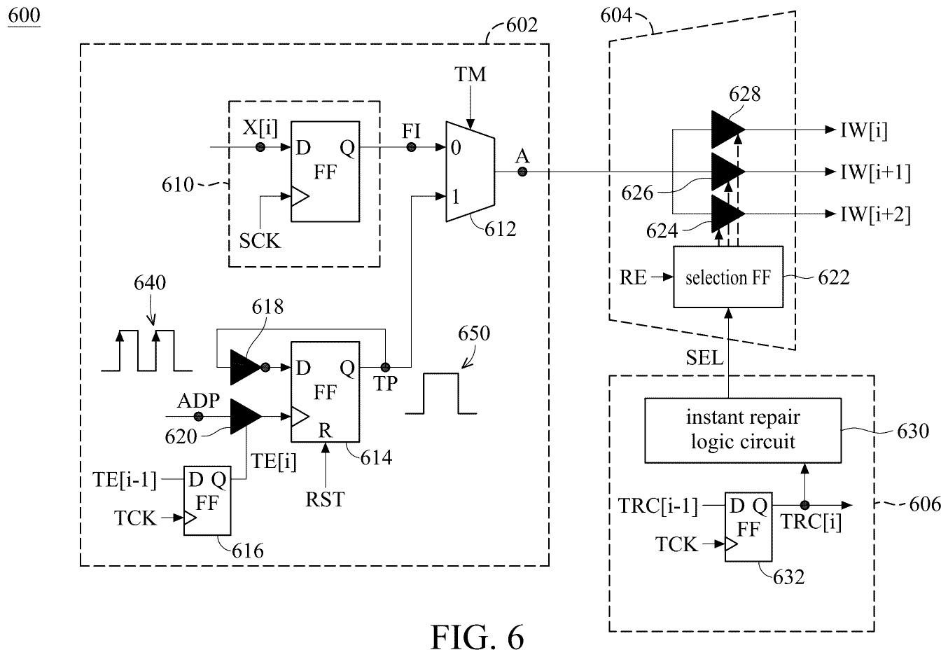

FIG. 6 is a schematic diagram of a driver unit 600 in a driver wrapper circuit 112 of the electronic device 100 in FIG. 1 in accordance with some embodiments of the present invention. As shown in FIG. 6, the driver unit 600 includes a transmitting unit 602, a selector 606, and a switch circuit 604. The transmitting unit 602 receives a double-pulse signal ADP (whose waveform is shown as a waveform 640), and generates a pulse signal TP (whose waveform is shown as a waveform 650) according to the double-pulse signal ADP. The selector 606 receives the test result TRC[i−1] of the pulse signal TP and outputs a selection signal SEL according to the test result TRC[i]. The switch circuit 604 sends the pulse signal TP to one of spare interconnects (e.g., an interconnect IW[i], an interconnect IW[i+1], an interconnect IW[i+2]) according to the selection signal SEL from the selector 606.

In detail, the transmitting unit 602 includes a flip-flop (FF) 610, a multiplexer 612, a flip-flop 614, a flip-flop 616, an inverter 618, and a switch 620. The flip-flop 610 is a D flip-flop. The flip-flop 610 includes a first input end, a second input end, and an output end. The multiplexer 612 includes a first input end, a second input end, an output end, and a control end. The first input end of the flip-flop 610 receives a data signal X[i]. The second input end of the flip-flop 610 receives a clock signal SCK. The output end of the flip-flop 610 outputs a functional input signal FI based on a rising edge of the clock signal SCK. The functional input signal FI is related to the data signal X[i]. The first input end of the multiplexer 612 receives the functional input signal FI. The second input end of the multiplexer 612 receives the pulse signal TP from the flip-flop 614. The control end of the multiplexer 612 receives a test command TM. When the multiplexer 612 receives the test command TM from the master controller 110, the multiplexer 612 outputs the pulse signal TP to a node A. When the multiplexer 612 does not receive the test command TM from the master controller 110, the multiplexer 612 outputs the functional input signal FI to the node A.

The flip-flop 614 is a D flip-flop. The flip-flop 614 includes a first input end, a second input end, a third input end, and an output end. The first input end of the flip-flop 614 is electrically connected to the output end of the inverter 618. The second input end of the flip-flop 614 is electrically connected to the output end of the switch 620. The third input end of the flip-flop 614 electrically receives a reset command RST. When the flip-flop 614 receives the reset command RST, the flip-flop 614 may be reset. The input end of the inverter 618 is electrically connected to the output end of the flip-flop 614. The switch 620 includes an input end, an output end, and a control end. The input end of the switch 620 receives the double-pulse signal ADP. The control end of the switch 620 receives a scan shift signal TE[i] from the flip-flop 616. For example, when the switch 620 receives the scan shift signal TE[1], the switch circuit 604 outputs the pulse signal TP to an interconnect IW[1]. When the switch 620 receives the scan shift signal TE[3], the switch circuit 604 outputs the pulse signal TP to an interconnect IW[3].

The flip-flop 616 is a D flip-flop. The flip-flop 616 includes a first input end, a second input end, and an output end. The first input end of the flip-flop 616 receives the scan shift signal TE[i−1]. The second input end of the flip-flop 616 receives the clock signal TCK. The output end of the flip-flop 616 outputs the scan shift signal TE[i] based on the rising edge of the clock signal TCK. The scan shift signal TE[i] is related to the scan shift signal TE[i−1].

The selector 606 includes an instant repair logic circuit 630 and a flip-flop 632. The flip-flop 632 is a D flip-flop. The flip-flop 632 includes a first input end, a second input end, and an output end. The first input end of the flip-flop 632 receives a test result TRC[i−1] of the pulse signal TP. The second input end of the flip-flop 632 receives the clock signal TCK. The output end of the flip-flop 632 outputs the test result TRC[i] based on the rising edge of the clock signal TCK. In some embodiments, the test result TRC[i] may be, for example, the first test result of the interconnects TSV1, the second test result of the interconnects TSV2, and the third test result of the interconnects TSV3. The instant repair logic circuit 630 outputs the selection signal SEL to the switch circuit 604 according to the test result TRC[i].

The switch circuit 604 includes a selection flip-flop 622, a switch 624, a switch 626, and a switch 628. The selection flip-flop 622 includes an input end, an output end, and a control end. The input end of the selection flip-flop 622 receives the selection signal SEL from the instant repair logic circuit 630. The control end of the selection flip-flop 622 receives a repair command RE. When the selection flip-flop 622 receives the repair command RE, the output end of the selection flip-flop 622 outputs an enable signal to the switch 624, the switch 626, and the switch 628 according to the selection signal SEL. The input ends of the switch 624, the switch 626, and the switch 628 all receive the pulse signal TP. The output end of the switch 628 is electrically connected to the interconnect IW[i]. The output end of switch 626 is electrically connected to the interconnect IW[i+1]. The output end of switch 624 is electrically connected to the interconnect IW[i+2]. The switch 628, the switch 626, and the switch 624 sequentially output the pulse signal TP to the interconnect IW[i], the interconnect IW[i+1], and the interconnect IW[i+2] according to the enable signal from the selection flip-flop 622.

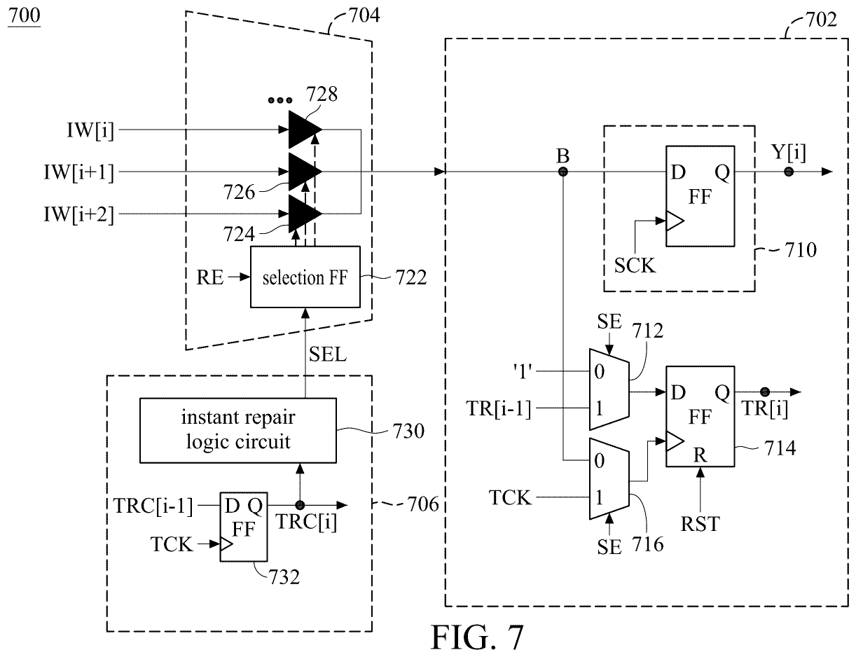

FIG. 7 is a schematic diagram of a receiver unit 700 in a receiver wrapper circuit 114 of the electronic device 100 in FIG. 1 in accordance with some embodiments of the present invention. As shown in FIG. 7, the receiver unit 700 includes a capturing unit 702, a selector 706, and a switch circuit 704. The capturing unit 702 receives the pulse signal that has passed through the interconnects TSV1, and generates test result TR[i] according to the pulse signal that has passed through the interconnects TSV1. The selector 706 receives a test result TRC[i−1] of the pulse signal, and outputs a selection signal SEL according to the test result TRC[i]. The switch circuit 704 receives the pulse signal through the aforementioned spare interconnect TSV1 according to the selection signal SEL from the selector 706.

In detail, the capturing unit 702 includes a flip-flop (FF) 710, a multiplexer 712, a flip-flop 714, and a multiplexer 716. The flip-flop 710 is a D flip-flop. The flip-flop 710 includes a first input end, a second input end, and an output end. The first input end of the flip-flop 710 receives the pulse signal from the switch circuit 704 through a node B. The second input end of the flip-flop 710 receives the clock signal SCK. The output end of the flip-flop 710 outputs the data signal Y[i] based on a rising edge of the clock signal SCK.

The flip-flop 714 is a D flip-flop. The flip-flop 714 includes a first input end, a second input end, a third input end, and an output end. The first input end of the flip-flop 714 is electrically connected to the output end of the multiplexer 712. The second input end of the flip-flop 714 is electrically connected to the output end of the multiplexer 716. The third input end of the flip-flop 714 receives the reset command RST. When the flip-flop 714 receives the reset command RST, the flip-flop 714 is reset. The multiplexer 712 includes a first input end, a second input end, a control end, and an output end. The first input end of the multiplexer 712 receives a logic high level signal, such as “1”. The second input end of the multiplexer 712 receives the test result TR[i−1]. The control end of the multiplexer 712 receives a scan enable signal SE. The multiplexer 716 includes a first input end, a second input end, a control end, and an output end. The first input end of the multiplexer 716 is electrically connected to the node B. The second input end of the multiplexer 716 receives the clock signal TCK. The control end of the multiplexer 716 receives the scan enable signal SE.

In some embodiments, when the scan enable signal SE is at a logic low level, such as “0”, the flip-flop 714 generates the test result TR[i] according to the pulse signal that has passed through the interconnect IW[i], the interconnect IW[i+1], or the interconnection lIW[i+2]. When the scan enable signal SE is at a logic high level, such as “1”, the test result TR[i] output by the flip-flop 714 is sent to the master controller 110 through the test result scan chain 140.

The selector 706 includes an instant repair logic circuit 730 and a flip-flop 732. The flip-flop 732 is a D flip-flop. The flip-flop 732 includes a first input end, a second input end, and an output end. The first input end of the flip-flop 732 receives the test result TRC[i−1] of the pulse signal TP. The second input end of the flip-flop 732 receives the clock signal TCK. The output end of the flip-flop 732 outputs the test result TRC[i] based on a rising edge of the clock signal TCK. In some embodiments, the test result TRC[i] may be, for example, the first test result of the interconnects TSV1, the second test result of the interconnects TSV2, and the third test result of the interconnects TSV3. The instant repair logic circuit 730 outputs the selection signal SEL to the switch circuit 704 according to the test result TRC[i].

The switch circuit 704 includes a selection flip-flop 722, a switch 724, a switch 726, and a switch 728. The selection flip-flop 722 includes an input end, an output end, and a control end. The input end of the selection flip-flop 722 receives the selection signal SEL from the instant repair logic circuit 730. The control end of the selection flip-flop 722 receives the repair command RE. When the selection flip-flop 722 receives the repair command RE, the output end of the selection flip-flop 722 outputs an enable signal to the switch 724, the switch 726, and the switch 728 according to the selection signal SEL. The input end of the switch 724 is electrically connected to the interconnect IW[i+2]. The input end of the switch 726 is electrically connected to interconnect IW[i+1]. The input end of switch 728 is electrically connected to interconnect IW[i]. The output ends of the switches 724, 726 and 728 are electrically connected to node B. The switches 728, 726, and 724 receive the pulse signals from the interconnect IW[i], the interconnect IW[i+1], and the interconnect IW[i+2] respectively according to the enable signal from the selection flip-flop 722.

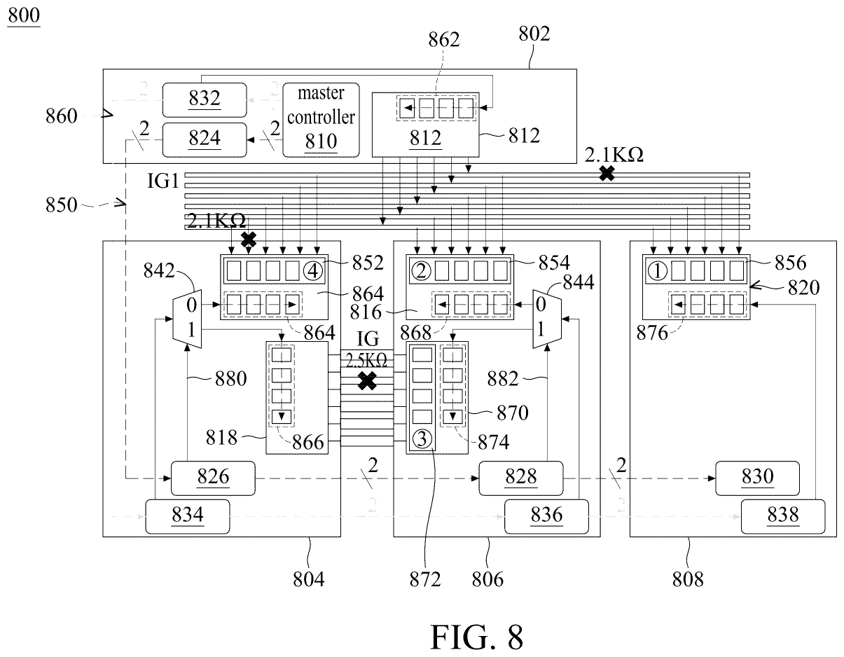

FIG. 8 is a schematic diagram of an electronic device 800 in accordance with some embodiments of the present invention. As shown in FIG. 8, the electronic device 800 includes a master die 802, a first middle slave die 804, a second middle slave die 806, an edge slave die 808, interconnects IG1, and interconnects IG2. The master die 802 is electrically connected to the first middle slave die 804, the second middle slave die 806, and the edge slave die 808 through the interconnects IG1. The first middle slave die 804 is electrically connected to the second middle slave die 806 through the interconnects IG2.

In some embodiments of FIG. 8, the master die 802 includes a master controller 810, a driver wrapper circuit 812, a control channel register 824, and a data channel register 832. The first middle slave die 804 includes a receiver wrapper circuit 814, a slave driver wrapper circuit 818, a control channel register 826, a data channel register 834, and a multiplexer 842. The second middle slave die 806 includes a receiver wrapper circuit 816, a receiver wrapper circuit 870, a control channel register 828, a data channel register 836, and a multiplexer 844. The edge slave die 108 includes a receiver wrapper circuit 820, a control channel register 830, and a data channel register 838.

In some embodiments of FIG. 8, the driver wrapper circuit 812 includes a register 862. The receiver wrapper circuit 814 includes a register 852 and a register 864. The slave driver wrapper circuit 818 includes a register 866. The receiver wrapper circuit 816 includes a register 854 and a register 868. The receiver wrapper circuit 870 includes a register 872 and a register 874. The receiver wrapper circuit 820 includes a register 856 and a register 876.

When the master controller 110 of the master die 802 sends the test command to the control channel register 824 of the master die 102 through the control channel 850, the driver wrapper circuit 812 of the master die 802 transmits a pulse signal to the interconnects IG1. The receiver wrapper circuit 814 of the first middle slave die 804 receives the pulse signal from the interconnects IG1 and obtains test result 4. The test result 4 are stored in the register 852 of the receiver wrapper circuit 814. The receiver wrapper circuit 816 of the second middle slave die 806 receives the pulse signal from the interconnects IG1 and obtains test result 2. The test result 2 are stored in the register 854 in receiver wrapper circuit 816. The receiver wrapper circuit 820 of the edge slave die 808 receives the pulse signal from interconnects IG1 to obtain test result 1. The test result 1 are stored in the register 856 in the receiver wrapper circuit 820.

In some embodiments of FIG. 8, the test result 4 record that the 5^{th} interconnect in the interconnects IG1 arranged from top to bottom is faulty. For example, the resistance of the 5^{th} interconnect is 2.1 kilo-ohms. The test result 2 record that all interconnects in the interconnects IG1 have passed the test. The test result 1 record that the 1^{st} interconnect in the interconnect IG1 from top to bottom is faulty, for example, the resistance of the 1^{st} interconnect is 2.1 kilo-ohms.

When the master controller 110 of the master die 802 sends the test command to the control channel register 826 of the first middle slave die 804 through the control channel 850, the slave driver wrapper circuit 818 of the first middle slave die 804 transmits a pulse signal to the interconnects IG2. The receiver wrapper circuit 870 of the second middle slave die 806 receives the pulse signal from the interconnects IG2 and obtains test result 3. The test result 3 are stored in the register 872 in receiver wrapper circuit 870. The test result 3 record that the 2^{nd} and 3^{rd} interconnects arranged from top to bottom in interconnects IG2 are faulty. For example, the resistance of the 2^{nd} and 3^{rd} interconnects is 2.5 kilo-ohms.

The master controller 810 sequentially receives the test result 1, the test result 2, the test result 3, and the test result 4 through a test result scan chain. Then, the master controller 810 sequentially sends the test result 1, the test result 2, the test result 3, and the test result 4 to the data register 832, the data register 834, the data register 836, and the data register 838 through the data channel 860.

When the master controller 110 of the master die 802 sends the synchronization command to the control channel register 824 of the master die 802, the control channel register 826 of the first middle slave die 804, the control channel register 828 of the second middle slave die 806, and the control channel register 830 of the edge slave die 808 through the control channel 850, the data channel register 832 sends the test result 1, the test result 2, and the test result 4 to the register 862 of the driver wrapper circuit 812. In order to synchronize the test result 4, the data channel register 834 sends the test result 4 to the register 864 of the receiver wrapper circuit 814. In detail, the control channel register 826 sends an address identification signal 880 to the multiplexer 842, so that the test result 4 is sent to the register 864.

In order to synchronize the test result 2, the data channel register 836 sends the test result 2 to the register 868 of the receiver wrapper circuit 816. In detail, the control channel register 828 sends an address identification signal 882 to the multiplexer 844, so that the test result 2 is sent to the register 868. In order to synchronize the test result 1, the data channel register 838 sends the test result 1 to the register 876 of the receiver wrapper circuit 820.

In order to synchronize the test result 3, the data channel register 834 sends the test result 3 to the register 866 of the slave driver wrapper circuit 818. In detail, the control channel register 826 sends the address identification signal 880 to the multiplexer 842, so that the test result 3 is sent to the register 866. In order to synchronize the test result 3, the data channel register 836 sends the test result 3 to the register 874 of the receiver wrapper circuit 870.

When the master controller 110 of the master die 802 sends the repair command to the control channel register 824 of the master die 802 through the control channel 850, the driver wrapper circuit 812 selects a spare interconnect in the interconnects IG1 according to the test result 1, the test result 2, and the test result 4 stored in the register 862.

When the master controller 110 of the master die 802 sends the repair command to the control channel register 826 of the first middle slave die 804 through the control channel 850, the receiver wrapper circuit 814 selects the spare interconnect in the interconnects IG1 according to the test result 4 stored in the register 864, and the slave driver wrapper circuit 818 selects a spare interconnect in the interconnects IG2 according to the test result 3 stored in the register 866.

When the master controller 110 of the master die 802 sends the repair command to the control channel register 828 of the second middle slave die 806 through the control channel 850, the receiver wrapper circuit 816 selects the spare interconnect in the interconnects IG1 according to the test result 2 stored in the register 868, and the receiver wrapper circuit 870 selects the spare interconnect in the interconnects IG2 according to the test result 3 stored in the register 874.

When the master controller 110 of the master die 802 sends the repair command to the control channel register 830 of the edge slave die 808 through the control channel 850, the receiver wrapper circuit 820 selects the spare interconnect in the interconnects IG1 according to the test result 1 stored in the register 876. In some embodiments, the master controller 810 sends the repair command to the control channel register 824 of the master die 802, the control channel register 826 of the first middle slave die 804, the control channel register 828 of the second middle slave die 806, and the control channel register 830 of the edge slave die 808 through the control channel 850.

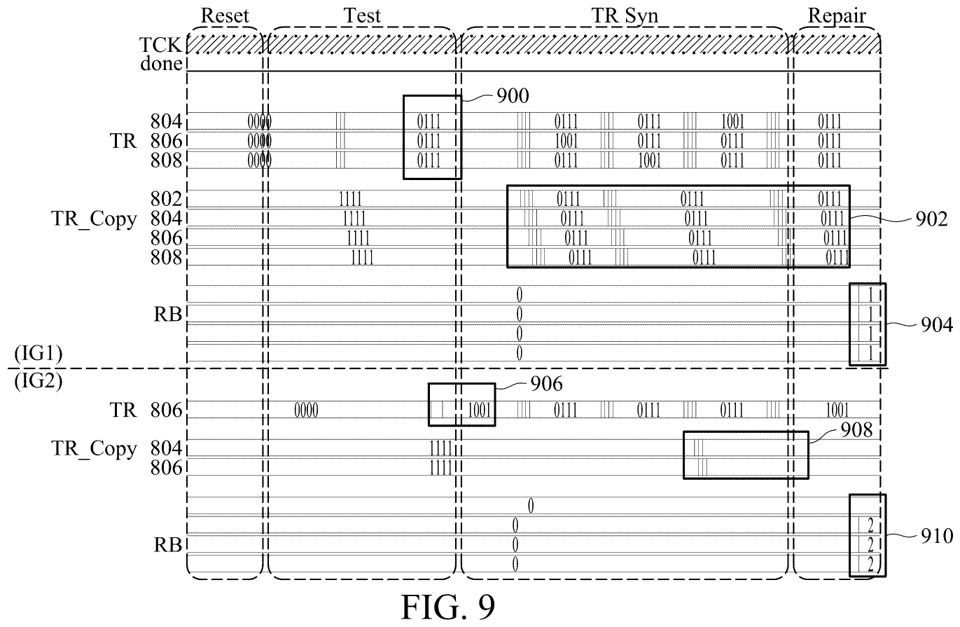

FIG. 9 is a waveform timing diagram of a first round of the method for self-repairing built-in interconnects in FIG. 2 executed by the electronic device 800 in FIG. 8 in accordance with some embodiments of the present invention. As shown in FIG. 9, in a reset mode (Reset), the master controller 810 sends the reset command to the control channel register 824 of the master die 802, the control channel register 826 of the first middle slave die 804, the control channel register 828 of the second middle slave die 806, and the control channel register 830 of the edge slave die 808 through the control channel 850, so that data stored in all registers in the electronic device 800 are reset. In a test mode (Test), the master controller 810 sends the test command to the control channel register 824 of the master die 802 through the control channel 850 to obtain the test result 1, the test result 2, and the test result 4 associated with the interconnects IG1. As shown in a block 900, the test result 4 are “0111”, the test result 2 are “0111”, and the test result 1 are “0111”.

In the test mode (Test), the master controller 810 sends the test command to the control channel register 826 of the first middle slave die 804 through the control channel 850 to obtain the test result 3 associated with the interconnects IG2. As shown in a block 906, the test result 3 are “1001”.

Next, in a synchronization mode (TR Syn), the master controller 810 sends the synchronization command to the control channel register 824 of the master die 802, the control channel register 826 of the first middle slave die 804, the control channel register 828 of the second middle slave die 806, and the control channel register 830 of the edge slave die 808 through the control channel 850. As shown in a block 902, the test result 1, the test result 2, and the test result 4 associated with the interconnects IG1 are sent to the driver wrapper circuit 812 of the master die 802. The fourth test result 4 associated with the interconnects IG1 is sent to the receiver wrapper circuit 814 of the first middle slave die 804. The second test result 2 associated with the interconnects IG1 is sent to the receiver wrapper circuit 816 of the second middle slave die 806. The first test result 1 associated with the interconnects IG1 is transmitted to the receiver wrapper circuit 820 of the edge salve die 808.

In the synchronization mode (TR Syn), the master controller 810 sends the synchronization command to the control channel register 826 of the first middle slave die 804 and the control channel register 828 of the second middle slave die 806 through the control channel 850. As shown in block 908, the third test result 3 associated with the interconnects IG2 is transmitted to the slave driver wrapper circuit 818 of the first middle slave die 804. The third test result 3 associated with the interconnects IG2 is sent to the receiver wrapper circuit 870 of the second middle slave die 806.

In a repair mode (Repair), the driver wrapper circuit 812 of the master die 802 repairs according to the first test result 1, the second test result 2, and the fourth test result 4 (for example, all are “0111”). The receiver wrapper circuit 814 of the first middle slave die 804 repairs according to the fourth test result 4 (e.g., “0111”). The receiver wrapper circuit 816 of the second middle slave die 806 repairs according to the second test result 2 (e.g., “0111”). The receiver wrapper circuit 820 of the edge slave die 808 repairs according to the first test result 1 (e.g., “0111”). As shown in a block 904, the first test result 1, the second test result 2, and the fourth test result 4 are all “0111”, so that a repair bit RB is “1111” (arranged from top to bottom in the block 904).

In the repair mode (Repair), the slave driver wrapper circuit 818 of the first middle slave die 804 repairs according to the third test result 3 (e.g., “1001”). The receiver wrapper circuit 870 of the second middle slave die 806 repairs according to the third test result 3 (e.g., “1001”). As shown in a block 910, the third test result 3 is “1001”, so that the repair bit RB is “0222” (arranged from top to bottom in the block 910).

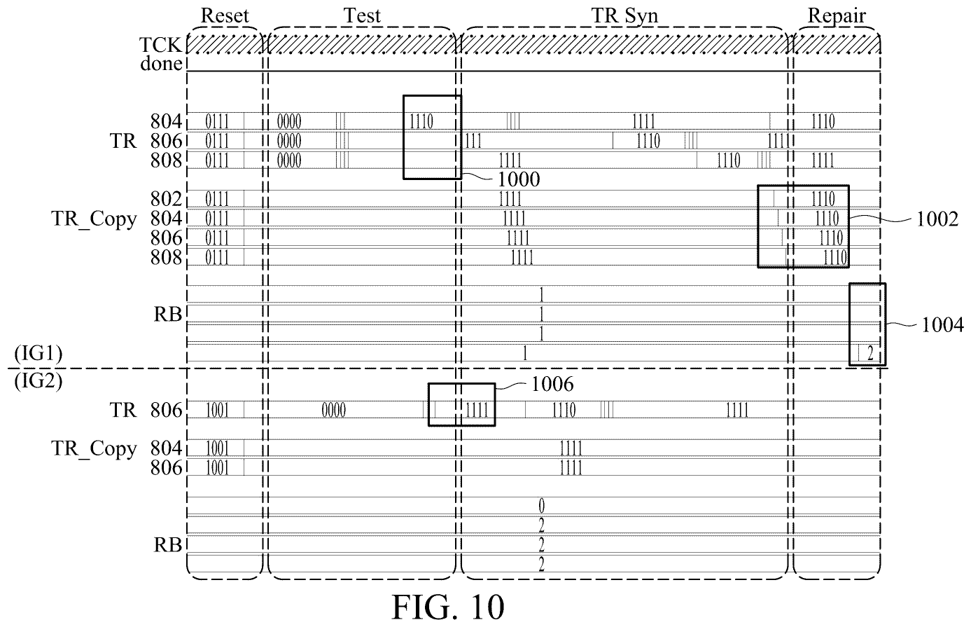

FIG. 10 is a waveform timing diagram of a second round of the method for self-repairing built-in interconnects in FIG. 2 executed by the electronic device 800 in FIG. 8 in accordance with some embodiments of the present invention. As shown in FIG. 10, in the reset mode (Reset), the master controller 810 sends the reset command to the control channel register 824 of the master die 802, the control channel register 826 of the first middle slave die 804, the control channel register 828 of the second middle slave die 806, and the control channel register 830 of the edge slave die 808 through the control channel 850, so that data stored in all registers in the electronic device 800 are reset. In the test mode (Test), the master controller 810 sends the test command to the control channel register 824 of the master die 802 through the control channel 850 to obtain the test result 1, the test result 2, and the test result 4 associated with the interconnects IG1. As shown in a block 1000, the test result 4 are “1110”, the test result 2 are “1111”, and the test result 1 are “1111”.

In the test mode (Test), the master controller 810 sends the test command to the control channel register 826 of the first middle slave die 804 through the control channel 850 to obtain the test result 3 associated with the interconnects IG2. As shown in a block 1006, the test result 3 are “1111”.

Next, in the synchronization mode (TR Syn), the master controller 810 sends the synchronization command to the control channel register 824 of the master die 802, the control channel register 826 of the first middle slave die 804, the control channel register 828 of the second middle slave die 806, and the control channel register 830 of the edge slave die 808 through the control channel 850. As shown in a block 1002, the test result 1, the test result 2, and the test result 4 associated with the interconnects IG1 are sent to the driver wrapper circuit 812 of the master die 802. The test result 4 associated with the interconnects IG1 is sent to the receiver wrapper circuit 814 of the first middle slave die 804. The test result 2 associated with the interconnects IG1 is sent to the receiver wrapper circuit 816 of the second middle slave die 806. The test result 1 associated with the interconnects IG1 is sent to the receiver wrapper circuit 820 of the edge slave die 808.

In the repair mode (Repair), the driver wrapper circuit 812 of the master die 802 repairs according to the test result 1, the test result 2, and the test result 4 (for example, all are “1110”). The receiver wrapper circuit 814 of the first middle slave die 804 repairs according to the test result 4 (for example, “1110”). The receiver wrapper circuit 816 of the second middle slave die 806 repairs according to the test result 2 (e.g., “1110”). The receiver wrapper circuit 820 of the edge slave die 808 repairs according to the test result 1 (e.g., “1110”). As shown in a block 1004, the test result 1, the test result 2, and the test result 4 are all “1110”, so that the repair bit RB is “0002” (arranged from top to bottom in the block 1004). Since the test result 3 is “1111”, the interconnects IG2 have passed the test.

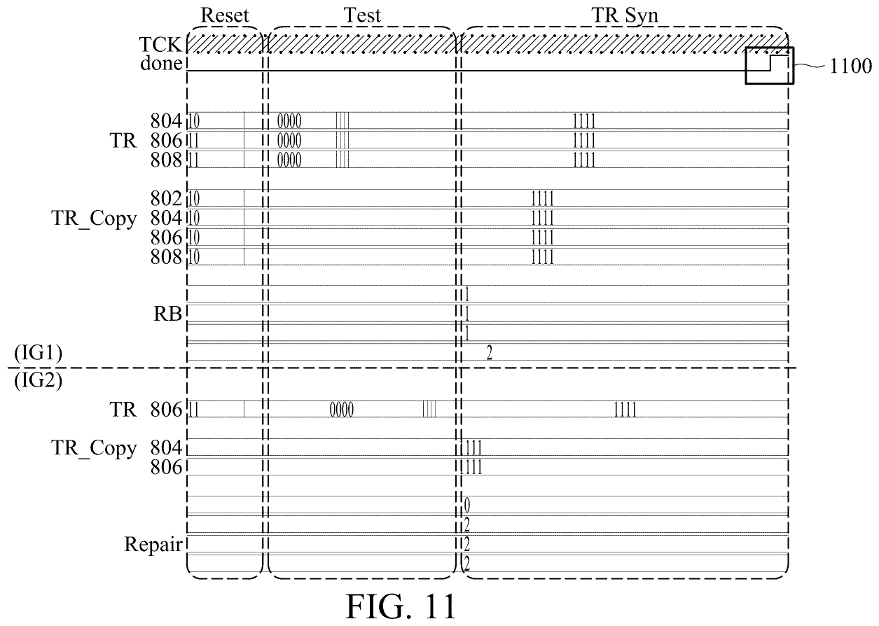

FIG. 11 is a waveform timing diagram of a third round of the method for self-repairing built-in interconnects in FIG. 2 executed by the electronic device 800 in FIG. 8 in accordance with some embodiments of the present invention. As shown in FIG. 11, in the reset mode (Reset), the master controller 810 sends the reset command to the control channel register 824 of the master die 802, the control channel register 826 of the first middle slave die 804, the control channel register 828 of the second middle slave die 806, and the control channel register 830 of the edge slave die 808 through the control channel 850, so that data stored in all registers in the electronic device 800 are reset.

In the test mode (Test), the master controller 810 sends the test command to the control channel register 824 of the master die 802 through the control channel 850 to obtain the test result 1, the test result 2, and the test result 4 associated with the interconnects IG1. As shown in a block 1000, the test result 4 are “1111”, the test result 2 are “1111”, and the test result 1 are “1111”.

Next, in the synchronization mode (TR Syn), the master controller 810 sends the synchronization command to the control channel register 824 of the master die 802, the control channel register 826 of the first middle slave die 804, the control channel register 828 of the second middle slave die 806, and the control channel register 830 of the edge slave die 808 through the control channel 850. The test result 1, the test result 2, and the test result 4 associated with the interconnects IG1 are sent to the driver wrapper circuit 812 of the master die 802. The test result 4 associated with the interconnects IG1 is sent to the receiver wrapper circuit 814 of the first middle slave die 804. The test result 2 associated with the interconnects IG1 is sent to the receiver wrapper circuit 816 of the second middle slave die 806. The test result 1 associated with the interconnects IG1 is sent to the receiver wrapper circuit 820 of the edge slave die 808. Since the test result 1, the test result 2, and the test result 3 associated with the interconnects IG1 are all “1111”, a block 1100 shows that a completion signal done is pulled high, and the interconnects IG1 and the interconnects IG2 have passed the test.

While the invention has been described by way of example and in terms of the preferred embodiments, it should be understood that the invention is not limited to the dis-closed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, comprising:
a plurality of interconnects, comprising multiple spare interconnects;
a plurality of dies, electrically connected to each other through the interconnects, comprising a master die and multiple slave dies;
wherein each slave die comprises:
a receiver wrapper circuit, configured to receive a pulse signal from the interconnects to obtain a test result;
wherein the master die comprises:
a master controller, configured to send out a mode configuration command;
a driver wrapper circuit, configured to transmit the pulse signal to the interconnects, and select one of the spare interconnects according to the test result;
wherein the master controller is configured to broadcast the test result to the driver wrapper circuit and the receiver wrapper circuit;
wherein the receiver wrapper circuit is configured to select the one of the spare interconnects according to the test result.

2. The electronic device as claimed in claim 1, wherein the mode configuration command comprises a reset command, a test command, a synchronization command, or a repair command.

3. The electronic device as claimed in claim 2, wherein the master die and each slave die comprise:
a control channel register, configured to receive the mode configuration command from the master controller through a control channel; and
a data channel register, configured to receive the test result from the master controller through a data channel, and send the test result to the driver wrapper circuit or the receiver wrapper circuit according to the synchronization command.

4. The electronic device as claimed in claim 3, wherein the slave dies comprise multiple middle slave dies and an edge slave die; the middle slave dies are electrically connected between the master die and the edge slave die; and each middle slave die comprises:
a slave driver wrapper circuit, configured to transmit the pulse signal to the interconnects according to the mode configuration command, or receive the test result from the master controller, or select the one of the spare interconnects according to the test result; and
a multiplexer, comprising an input end, a first output end, a second output end, and a control end; wherein the input end is electrically connected to the data channel register, the first output end is electrically connected to the receiver wrapper circuit, the second output end is electrically connected to the slave driver wrapper circuit, and the control end is electrically connected to the control channel register.

5. The electronic device as claimed in claim 4, wherein the multiplexer sends data stored in the data channel register to the receiver wrapper circuit or the slave driver wrapper circuit according to an address identification signal; the control channel register of each middle slave die sends the address identification signal to the multiplexer.

6. The electronic device as claimed in claim 4, wherein the slave dies comprise a first middle slave die and a second middle slave die; the interconnects comprise a first interconnect group, a second interconnect group, and a third interconnect group; the first interconnect group is electrically connected between the master die and the first middle slave die; the second interconnect group is electrically connected between the first middle slave die and the second middle slave die; and the third interconnect group is electrically connected between the second middle slave die and the edge slave die.

7. The electronic device as claimed in claim 6, wherein the master controller sequentially sends the test command to the control channel register of the master die, the control channel register of the first middle slave die, and the control channel register of the second middle slave die through the control channel, so that the driver wrapper circuit transmits the pulse signal to the first interconnect group, then the slave driver wrapper circuit of the first middle slave die transmits the pulse signal to the second interconnect group, and finally the slave driver wrapper circuit of the second middle slave die transmits the pulse signal to the third interconnect group.

8. The electronic device as claimed in claim 7, wherein the receiver wrapper circuit of the first middle slave die receives the pulse signal from the first interconnect group to obtain a first test result; the receiver wrapper circuit of the second middle slave die receives the pulse signal from the second interconnect group to obtain a second test result; and the receiver wrapper circuit of the edge slave die receives the pulse signal from the third interconnect group to obtain a third test result.

9. The electronic device as claimed in claim 8, wherein the master controller receives the first test result, the second test result, and the third test result through a test result scan chain.

10. The electronic device as claimed in claim 9, wherein the master controller sequentially sends the first test result, the second test result, and the third test result to the data channel register of the master die, the data channel register of the first middle slave die, the data channel register of the second middle slave die, and the data channel register of the edge slave die through the data channel.

11. The electronic device as claimed in claim 10, wherein the master controller sends the synchronization command to the control channel register of the master die and the control channel register of the first middle slave die through the control channel, so that the data channel register of the master die sends the first test result to the driver wrapper circuit of the master die, and the data channel register of the first middle slave die sends the first test result to the receiver wrapper circuit of the first middle slave die.

12. The electronic device as claimed in claim 11, wherein the master controller sends the synchronization command to the control channel register of the first middle slave die and the control channel register of the second middle slave die through the control channel, so that the data channel register of the first middle slave die sends the second test result to the slave driver wrapper circuit of the first middle slave die, and the data channel register of the second middle slave die sends the second test result to the receiver wrapper circuit of the second middle slave die.

13. The electronic device as claimed in claim 12, wherein the master controller sends the synchronization command to the control channel register of the second middle slave die and the control channel register of the edge slave die through the control channel, so that the data channel register of the second middle slave die sends the third test result to the slave driver wrapper circuit of the second middle slave die, and the data channel register of the edge slave die sends the third test result to the receiver wrapper circuit of the edge slave die.

14. The electronic device as claimed in claim 13, wherein the master controller sends the repair command to the control channel register of the master die, so that the driver wrapper circuit of the master die selects a spare interconnect in the first interconnect group according to the first test result to eliminate a faulty interconnect in the first interconnect group.

15. The electronic device as claimed in claim 13, wherein the master controller sends the repair command to the control channel register of the first middle slave die, so that the receiver wrapper circuit of the first middle slave die selects a spare interconnect in the first interconnect group according to the first test result to eliminate a faulty interconnect in the first interconnect group, and the slave driver wrapper circuit of the first middle slave die selects a spare interconnect in the second interconnect group according to the second test result to eliminate a faulty interconnect in the second interconnect group.

16. The electronic device as claimed in claim 13, wherein the master controller sends the repair command to the control channel register of the second middle slave die, so that the receiver wrapper circuit of the second middle slave die selects a spare interconnect in the second interconnect group according to the second test result to eliminate a faulty interconnect in the second interconnect group, and the slave driver wrapper circuit of the second middle slave die selects a spare interconnect in the third interconnect group according to the third test result to eliminate a faulty interconnect in the third interconnect group.

17. The electronic device as claimed in claim 13, wherein the master controller sends the repair command to the control channel register of the edge slave die, so that the receiver wrapper circuit of the edge slave die selects a spare interconnect in the third interconnect group according to the third test result to eliminate a faulty interconnect in the third interconnect group.

18. The electronic device as claimed in claim 4, wherein the driver wrapper circuit or the slave driver wrapper circuit comprises a plurality of driver units, and each driver unit comprises:
a transmitting unit, configured to receive a double-pulse signal and generate the pulse signal according to the double-pulse signal;
a selector, configured to receive the test result of the pulse signal, and output a selection signal according to the test result; and
a switch circuit, configured to send the pulse signal to the one of the spare interconnects according to the selection signal from the selector.

19. The electronic device as claimed in claim 4, wherein the receiver wrapper circuit comprises a plurality of receiver units, and each receiver unit comprises:
a capturing unit, configured to receive the pulse signal that has passed through the interconnects, and generate the test result according to the pulse signal that has passed through the interconnects;
a selector, configured to receive the test result of the pulse signal, and output a selection signal according to the test result; and
a switch circuit, configured to receive the pulse signal through the one of the spare interconnects according to the selection signal from the selector.
